(19) United States
(12) Patent Application Publication
(10) Pub. No.: US 2025/0120057 A1
(43) Pub. Date: Apr. 10, 2025

(54) ARTICLE MANAGEMENT DEVICE AND ARTICLE MANAGEMENT METHOD

(71) Applicant: FUJI CORPORATION, Chiryu (JP)

(72) Inventors: Masafumi AMANO, Okazaki-shi (JP); Masanori KAWAGUCHI, Kariya-shi (JP); Go UCHIDA, Chiryu-shi (JP)

(73) Assignee: FUJI CORPORATION, Chiryu (JP)

(21) Appl. No.: 18/729,274

(22) PCT Filed: Jan. 28, 2022
(86) PCT No.: PCT/JP2022/003271

§ 371 Date: Jul. 16, 2024

(51) Int. Cl. H05K 13/08; H05K 13/02

(52) U.S. Cl. CPC H05K 13/0895; H05K 13/021; H05K 13/086

(57) ABSTRACT

An article management device includes a determination section and a change section. The determination section determines whether there is an abnormality in multiple board work machines configured to perform a predetermined board work on a board. The change section changes a degree of priority of a replenishment work of replenishing the multiple board work machines with articles used in the multiple board work machines based on a type of abnormality in an abnormal work machine that is at least one of the multiple board work machines determined to have an abnormality by the determination section.

### TECHNICAL FIELD

The present description discloses a technique related to an article management device and an article management method.

### BACKGROUND ART

The support work management device described in Patent Literature 1 manages the member replenishment work and the recovery work in the support work. Support work basic information, which is basic information of various support works managed by a support work management device, is stored in a storage device of the support work management device as a support work master file. In the support work master file, information relating to the name, the type, the target work machine, the presence or absence of the down of the work machine, the required skill level, the standard required time, the arrival time adjustment time, the priority adjustment time, and the replenishment member acquisition time of the support work is recorded.

The standard required time refers to an indication of a time required to perform the support work. The priority adjustment time is a time for obtaining the priority determination time based on the recommended arrival time. The priority determination time is a type of the degree of priority based on the execution time of the support work, and the degree of priority assigned to a worker is higher as the priority determination time of the support work is earlier.

### PATENT LITERATURE

Patent Literature 1: WO2005/009101

### SUMMARY OF THE INVENTION

### Technical Problem

When an abnormality occurs in at least one of the multiple of board work machines that perform a predetermined board work on a board, the degree of priority of the replenishment work of replenishing the board work machine in which the abnormality has occurred with an article decreases. In this case, if the replenishment work of an article is performed based on the degree of priority set in advance, there is a possibility that the overall production efficiency of the multiple board work machines decreases.

In view of such circumstances, the present description discloses an article management device and an article management method capable of reviewing the degree of priority of a replenishment work of replenishing multiple board work machines with articles when an abnormality occurs in at least one of the multiple board work machines.

### Solution to Problem

The present description discloses an article management device including a determination section and a change section. The determination section determines whether there is an abnormality in multiple board work machines that perform a predetermined board work on a board. The change section changes a degree of priority of a replenishment work of replenishing the multiple board work machines with articles used in the multiple board work machines based on a type of abnormality in an abnormal work machine that is at least one of the multiple board work machines determined to have an abnormality by the determination section.

The present description also discloses an article management method including a determination step and a change step. In the determination step, it is determined whether there is an abnormality in multiple board work machines that perform a predetermined board work on a board. In the change step, a degree of priority of a replenishment work of replenishing the multiple board work machines with articles used in the multiple board work machines is changed based on a type of abnormality in an abnormal work machine that is at least one of the multiple board work machines determined to have an abnormality by the determination step.

### Advantageous Effect of the Invention

An article management device includes a determination section and a change section. Accordingly, the article management device can change the degree of priority of the replenishment work of an article based on the type of abnormality of an abnormal work machine in which an abnormality has occurred. The above description of the article management device can be similarly applied to an article management method.

### BRIEF DESCRIPTION OF DRAWINGS

FIG. 1 is a configuration view illustrating an example of the configuration of a production facility.

FIG. 2A is a perspective view illustrating an example of a feeder equipped with a reel.

FIG. 2B is a plan view illustrating an example of a tray pallet equipped with a component tray.

FIG. 3A is a front view illustrating an example of a storage cabinet.

FIG. 3B is a plan view of the storage cabinet of FIG. 3A.

FIG. 3C is a front view illustrating an example of a receiving section.

FIG. 4 is a block view illustrating an example of a control block of an article management device.

FIG. 5 is a flowchart illustrating an example of a control procedure by the article management device.

FIG. 6 is a schematic view illustrating an example of the relationship between the type of abnormality (error code) of a board work machine and a required recovery time.

FIG. 7 is a schematic view illustrating an example of a scheduled unloading time and a scheduled conveyance time of articles to be replenished to multiple board work machines.

FIG. 8 is a schematic view illustrating an example of a state in which the degree of priority (unloading order and conveyance order) of the replenishment work of an article is changed.

FIG. 9 is a schematic view illustrating another example of a state in which the degree of priority (unloading order and conveyance order) of the replenishment work of an article is changed.

FIG. 10 is a schematic view illustrating an example of a state in which the degree of priority (unloading order and conveyance order) of the replenishment work of an article is changed again.

### DESCRIPTION OF EMBODIMENTS

### 1. Embodiments

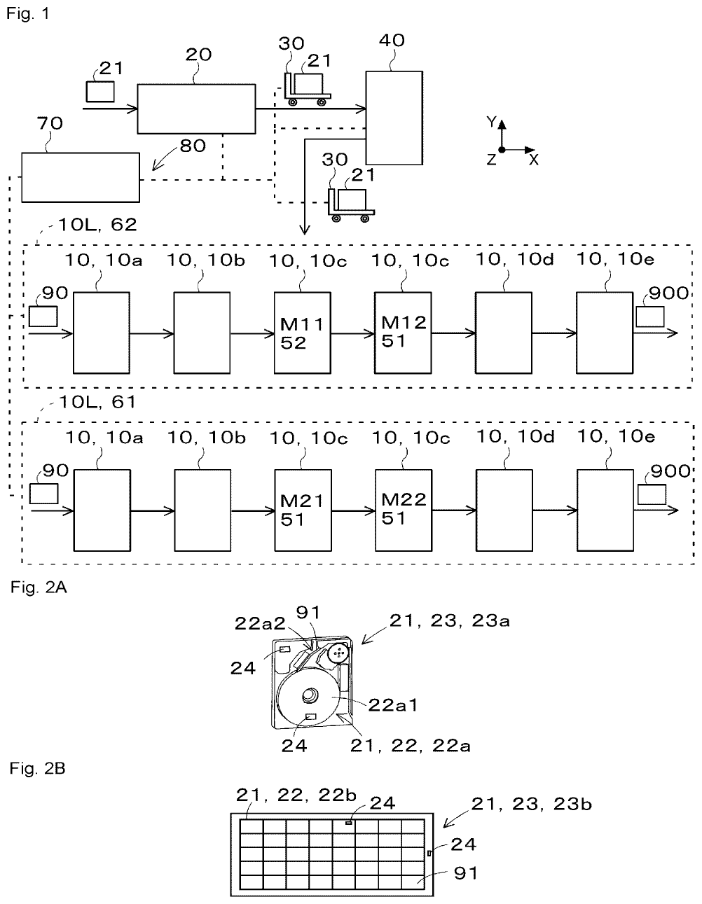

FIG. 1 illustrates an example of a production facility to which article management device 80 is applied. The production facility shown in FIG. 1 includes at least one (two in FIG. 1) production line 10L including multiple (six in FIG. 1) board work machines 10, arrival section 20, automated conveyance vehicle 30, storage cabinet 40, and management device 70.

### 1-1. Production Line 10L and Management Device 70

In each of two production lines 10L, multiple (six) board work machines 10 perform a predetermined board work on board 90. The type and number of board work machines 10 are not limited. As illustrated in FIG. 1, each of two production lines 10L includes board work machine 10 including printer 10a, print inspection machine 10b, component mounter 10c, reflow oven 10d, and visual inspector machine 10e, and board 90 is conveyed in the above order by a board conveyance device.

Printer 10a prints solder on the mounting position of component 91 of board 90. Print inspection machine 10b inspects the print state of solder which is printed by printer 10a. Component mounter 10c mounts multiple components 91 on board 90 on which solder is printed. One component mounter 10c may be provided, or multiple component mounters 10c may be provided. As illustrated in FIG. 1, when multiple (two in FIG. 1) component mounters 10c are provided, multiple (two) component mounters 10c are shared, and multiple components 91 can be mounted on board 90).

Component mounter 10c includes a component supply device that supplies component 91 to be mounted on board 90. The component supply device can supply components 91 by using, for example, feeder 23a equipped with reel 22a illustrated in FIG. 2A, tray pallet 23b equipped with component tray 22b illustrated in FIG. 2B, and the like. In reel 22a, carrier tape 22a2 accommodating component 91 to be mounted on board 90 is wound around main body portion 22a1. Reel 22a is rotatably and detachably equipped on feeder 23a. The tip portion of carrier tape 22a2 is drawn to the collection position, and components 91 are subsequently supplied to the collection position. Reel 22a can supply relatively small components 91 such as a chip component and the like.

Components 91 are arranged in component tray 22b. Component tray 22b supplies component 91 at the collection position in a state of being equipped in tray pallet 23b. Component tray 22b can supply relatively large components 91 such as a quad flat package (QFP), a ball grid array (BGA), and the like. Reflow oven 10d heats board 90 on which component 91 is mounted by component mounter 10c, melts the solder, and performs soldering. Visual inspector 10e inspects the mounting state of component 91 mounted on board 90) by component mounter 10c.

In this way, each of two production lines 10L may use multiple (six) board work machines 10 to convey boards 90 in order, execute production processing including inspection processing, and produce board products 900. Production line 10L may include board work machines 10 such as a function inspector, a buffer device, a board supply device, a board reversing device, a shield mounting device, an adhesive coating device, and an ultraviolet irradiation device as needed.

Production line 10L, arrival section 20, automated conveyance vehicle 30, storage cabinet 40, and management device 70 are provided to be able to communicate with each other by a wired or wireless communication section. For example, management device 70 controls board work machine 10 and monitors the operation state of board work machine 10. Management device 70 stores various kinds of control data for controlling board work machine 10. Management device 70) transmits control data to board work machine 10. Further, board work machine 10 transmits the operation state and the production state to management device 70).

### 1-2. Arrival Section 20 and Automated Conveyance Vehicle 30

The production facility of the embodiment includes at least one arrival section 20 and at least one automated conveyance vehicle 30. For example, when article 21 arrives at arrival section 20, the following loading work is performed. Then, article 21 is, for example, accommodated in an accommodation case, is mounted on automated conveyance vehicle 30, and is conveyed to storage cabinet 40. After being stored in storage cabinet 40, article 21 is supplied to production line 10L as needed.

Article 21 is not limited as long as article 21 is used in board work machine 10. Production line 10L of the embodiment includes component mounter 10c that mounts component 91 on board 90. In this case, for example, article 21 includes component container 22 that accommodates component 91 to be mounted on board 90 or component supply unit 23 that supplies component 91 accommodated in component container 22 to the collection position.

Reel 22a around which carrier tape 22a2 accommodating component 91 to be mounted on board 90 is wound is included in component container 22. Feeder 23a equipped with reel 22a is included in component supply unit 23. Component tray 22b in which components 91 are arranged is included in component container 22. Tray pallet 23b equipped with component tray 22b is included in component supply unit 23.

In addition, production line 10L of the embodiment includes printer 10a that prints solder at the mounting position of component 91 of board 90. In this case, for example, article 21 includes a solder container that accommodates solder. The solder container is provided at a predetermined portion of printer 10a and supplies solder to printer 10a.

Identification code 24 for identifying article 21 is attached to article 21. As identification code 24, for example, a one-dimensional code, a two-dimensional code, a wireless tag, or the like can be used. For example, when article 21 arrives at arrival section 20, a worker issues identification information by using management device 70. In addition, the worker reads a barcode or the like attached to article 21 by a supplier (vendor) by using a barcode reader or the like. Then, the worker can also acquire article information from a database in which article information related to article 21 is registered. The worker issues identification code 24 including at least identification information among identification information and article information by using management device 70.

The worker attaches identification code 24 including at least identification information to article 21 and accommodates article 21 in the accommodation case. The accommodation case only needs to be able to accommodate at least one article 21, and can take various forms. Further, a specific code for specifying the accommodation case is attached to the accommodation case. For example, a one-dimensional code, a two-dimensional code, a wireless tag, or the like can be used for the specific code.

The worker mounts the accommodation case accommodating article 21 onto automated conveyance vehicle 30. Automated conveyance vehicle 30 conveys the accommodation case accommodating article 21 to storage cabinet 40 based on a command from management device 70. Automated conveyance vehicle 30 can convey article 21 to storage cabinet 40 without using the accommodation case. As described above, automated conveyance vehicle 30 may be any known automated conveyance vehicle as long as automated conveyance vehicle 30 can convey article 21.

The worker can also convey article 21 or the accommodation case accommodating article 21 to storage cabinet 40 without using automated conveyance vehicle 30. Further, at least a part of the work performed by the worker described above can be automated by using a conveyance device (for example, a belt conveyor and the like), an actuator (for example, a robot arm and the like), management device 70, and the like.

### 1-3. Storage Cabinet 40

The production facility of the embodiment includes at least one storage cabinet 40. When article 21 is loaded through loading port 40a, storage cabinet 40 uses transfer device 45 to move article 21 to receiving section 44 for storage. Further, when article 21 stored in receiving section 44 is unloaded, storage cabinet 40 moves article 21 stored in receiving section 44 to work space 44a close to unloading port 40b by using transfer device 45 so that article 21 can be unloaded. Similarly, storage cabinet 40 can load and unload, and store the accommodation case accommodating at least one article 21.

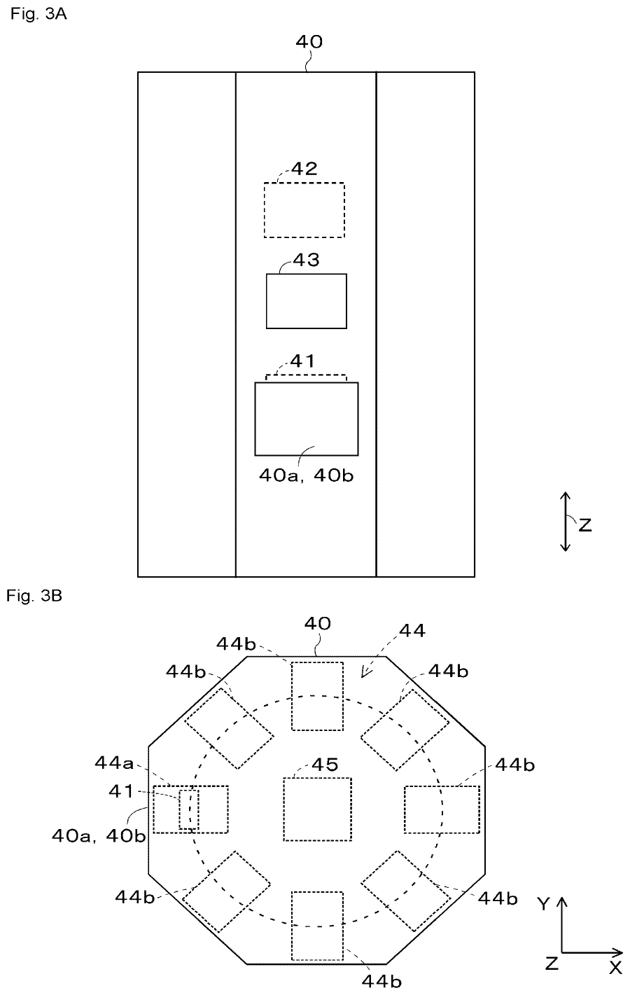

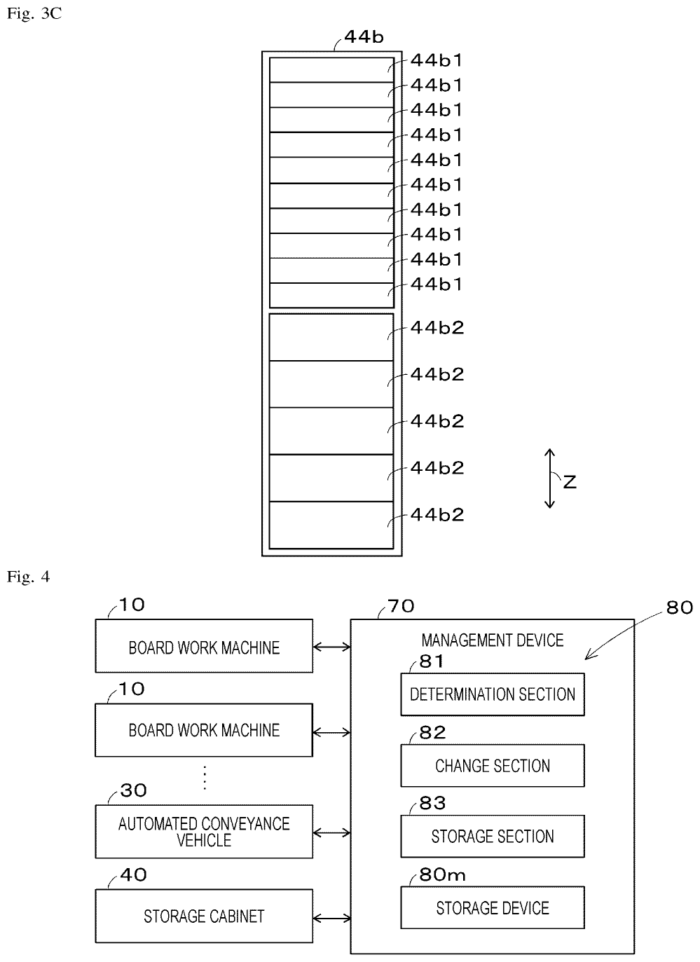

As described above, storage cabinet 40 can take various forms as long as storage cabinet 40 can store article 21 or the accommodation case because the loading and unloading of article 21 or the accommodation case is automated. As illustrated in FIGS. 3A and 3B, storage cabinet 40 of the embodiment is formed in, for example, an octagonal prism shape. Further, storage cabinet 40 of the embodiment includes loading port 40a, unloading port 40b, reading device 41, control device 42, display device 43, receiving section 44, and transfer device 45. Articles 21 are loaded into storage cabinet 40 through loading port 40a, and unloaded through unloading port 40b. Loading port 40a and unloading port 40b of the embodiment are provided in a common opening portion. Loading port 40a and unloading port 40b may also be provided in different opening portions.

Reading device 41 is provided above work space 44a close to loading port 40a. When article 21 is loaded into storage cabinet 40, reading device 41 reads identification code 24 attached to loaded article 21 to acquire identification information for identifying loaded article 21. As reading device 41, a known reading device (for example, a code reader that reads a one-dimensional code or a two-dimensional code) may be used. Further, when identification code 24 is a wireless tag, storage cabinet 40) may include a wireless device capable of wirelessly communicating with identification code 24.

Control device 42 includes a well-known computing device and storage device, and a control circuit is configured. Further, control device 42 is communicably connected to reading device 41, display device 43, receiving section 44, and transfer device 45, and can control the same. For example, control device 42 can control reading device 41. Further, control device 42 can acquire the identification information acquired by reading device 41 from reading device 41.

Further, control device 42 is provided so as to be able to communicate with management device 70 shown in FIG. 1 by a wired or wireless communication section. For example, management device 70 notifies control device 42 of the occurrence of a setup change in production line 10L. Management device 70 can also notify control device 42 of the occurrence of shortage of article 21 used in board work machine 10. Management device 70 can also notify control device 42 of a possibility that a setup change occurs in a predetermined period. Management device 70 can also notify control device 42 of a possibility that article 21 runs short in a predetermined period. Control device 42 causes necessary article 21 to be unloaded based on these notifications.

As display device 43, a well-known display device may be used, and displays various information so that the worker can visually recognize the information. Display device 43 displays, for example, article information indicating information on articles 21 received in receiving section 44, and the like according to an operation of the worker. The article information can include, for example, the type, the model, and the stock quantity of article 21. In addition, the article information can include the type, the model, the vendor name, the remaining quantity, the humidity management level, the expiration date of the content such as component 91 accommodated in article 21.

In addition, control device 42 can store positional information, loading and unloading information, and storage information of article 21 in receiving section 44 in the storage device, and display device 43 can also display these pieces of information. The positional information includes information indicating the location of article 21 received. The loading and unloading information includes information indicating the loading date and time and the unloading date and time of article 21. The storage information includes information relating to at least the atmospheric humidity among the atmospheric temperature and the atmospheric humidity of receiving section 44. Control device 42 stores the positional information and the loading date and time of article 21 in the storage device when article 21 is received. The control device 42 stores the storage information in the storage device during storage of article 21. Control device 42 stores the unloading date and time of article 21 in the storage device when article 21 is unloaded. Control device 42 can also store the number of times of loading and unloading in the storage device for each type of article 21.

Display device 43 of the embodiment includes a touch panel, and display device 43 also functions as an input device of receiving various operations by the worker. For example, the worker can specify desired article 21 to be unloaded from storage cabinet 40 by operating the touch panel. In this case, control device 42 causes article 21 specified by the worker to be unloaded from storage cabinet 40.

The above description of article 21 can be similarly applied to the accommodation case that accommodates at least one article 21. However, in this case, when article 21 is accommodated in the accommodation case, the worker reads the specific code attached to the accommodation case and identification code 24 attached to article 21 by using a code reader or the like. Accordingly, specific information for specifying the accommodation case and the identification information for identifying article 21 are associated with each other and stored in the storage device of management device 70.

When the accommodation case is loaded, reading device 41 reads the specific code attached to the accommodation case to acquire specific information for specifying the loaded accommodation case. Control device 42 acquires the identification information of article 21 accommodated in the accommodation case loaded in storage cabinet 40) based on the correspondence relationship between the specific information and the identification information stored in the storage device of management device 70. Accordingly, control device 42 can recognize article 21 accommodated in the accommodation case loaded in storage cabinet 40.

Receiving section 44 can take various forms as long as receiving section 44 can receive article 21 or the accommodation case. As illustrated in FIG. 3B, receiving section 44 of the embodiment includes multiple receiving units 44b, and multiple receiving units 44b are arranged in a circular shape when viewed in the vertical direction (Z-axis direction). Further, as illustrated in FIG. 3C, receiving unit 44b includes, for example, two types of receiving spaces, receiving space 44b1 and receiving space 44b2.

Multiple receiving spaces 44b1 and multiple receiving spaces 44b2 may be provided along the vertical direction (Z-axis direction). For example, the size (width dimension, depth dimension, and height dimension) of receiving space 44b1 is set to receive article 21. The size (width dimension, depth dimension, and height dimension) of receiving space 44b2 is set to receive the accommodation case accommodating article 21.

Transfer device 45 is provided inside multiple receiving units 44b when viewed in the vertical direction (Z-axis direction), and grips and moves article 21 or the accommodation case. Transfer device 45 can take various forms as long as transfer device 45 can grip and move article 21 or the accommodation case. For example, a robot arm (an articulated robot), a lifting and lowering slide mechanism, and the like may be used for transfer device 45.

In transfer device 45, a gripper grips article 21 or the accommodation case carried into work space 44a through loading port 40a during loading. Transfer device 45 moves the gripper to a predetermined receiving space and releases the gripping of article 21 or the accommodation case by the gripper. Thus, article 21 or the accommodation case is received in a predetermined receiving space. Further, in transfer device 45, the gripper grips article 21 or the accommodation case received in the predetermined receiving space during unloading. Transfer device 45 moves the gripper to work space 44a and releases the gripping of article 21 or the accommodation case by the gripper. Accordingly, article 21 or the accommodation case can be carried out. Article 21 or the accommodation case may be carried in and out by the worker or may be carried in and out by a robot arm, automated conveyance vehicle 30, or the like.

### 1-4. Article Management Device 80

For example, management device 70 calculates an expected time at which component 91 runs short in component mounter 10c based on the remaining quantity of components 91 in component mounter 10c and the usage amount of component 91 per unit time. Then, management device 70 issues a warning to prompt the worker to replenish component 91 earlier by a predetermined time than the expected time (component shortage notice).

In conjunction with the component shortage notice, management device 70 notifies control device 42 of storage cabinet 40 of the possibility that article 21 (in this case, for example, component container 22 or component supply unit 23) runs short in a predetermined period (an instruction to unload article 21 by the component shortage notice). Control device 42 causes necessary article 21 to be unloaded from storage cabinet 40) based on the notification. Further, management device 70 notifies automated conveyance vehicle 30 of a command to convey article 21 unloaded from storage cabinet 40 to component mounter 10c (an instruction to convey article 21 by the component shortage notice). Automated conveyance vehicle 30 conveys article 21 unloaded from storage cabinet 40 to component mounter 10c based on the notification.

In the above embodiment, it is assumed that an abnormality occurs in at least one of multiple component mounters 10c. In this case, the time at which article 21 is required in component mounter 10c in which an abnormality has occurred is later than the expected time calculated by management device 70 before the occurrence of the abnormality. That is, the degree of priority of the replenishment work of replenishing component mounter 10c in which the abnormality has occurred with article 21 decreases. The above description of the replenishment work in component mounter 10c can be similarly applied to the replenishment work in another board work machine 10 (for example, the replenishment work of solder in printer 10a).

As described above, when an abnormality occurs in at least one of multiple board work machines 10 that perform the predetermined board work on board 90, the degree of priority of the replenishment work of replenishing board work machine 10 in which the abnormality has occurred with article 21 decreases. In this case, when the replenishment work of article 21 is performed based on the degree of priority set in advance, there is a possibility that the overall production efficiency of multiple board work machines 10 decreases.

For example, the production facility illustrated in FIG. 1 includes two production lines 10L. When an abnormality occurs in board work machine 10 provided in one production line 10L of two production lines 10L, production line 10L temporarily stops the production of board product 900 until the abnormality of board work machine 10 is recovered. Therefore, if it is possible to prioritize the replenishment work of article 21 in board work machine 10 provided in other production line 10L of two production lines 10L, there is a possibility that it is possible to suppress a decrease in the overall production efficiency of multiple board work machines 10.

The production facility of the embodiment is provided with article management device 80. Article management device 80 changes the degree of priority of the replenishment work of article 21 based on the type of abnormality of abnormal work machine 52 in which an abnormality has occurred. Specifically, article management device 80 includes determination section 81 and change section 82. Article management device 80 may include storage section 83. As shown in FIG. 4, article management device 80 of the embodiment includes determination section 81, change section 82, and storage section 83.

Determination section 81, change section 82, and storage section 83 can be provided in various control devices. For example, at least one of determination section 81, change section 82, and storage section 83 may be provided in management device 70. At least one of determination section 81, change section 82, and storage section 83 may be provided in control device 42 of storage cabinet 40. At least one of determination section 81, change section 82, and storage section 83 may be formed on a cloud.

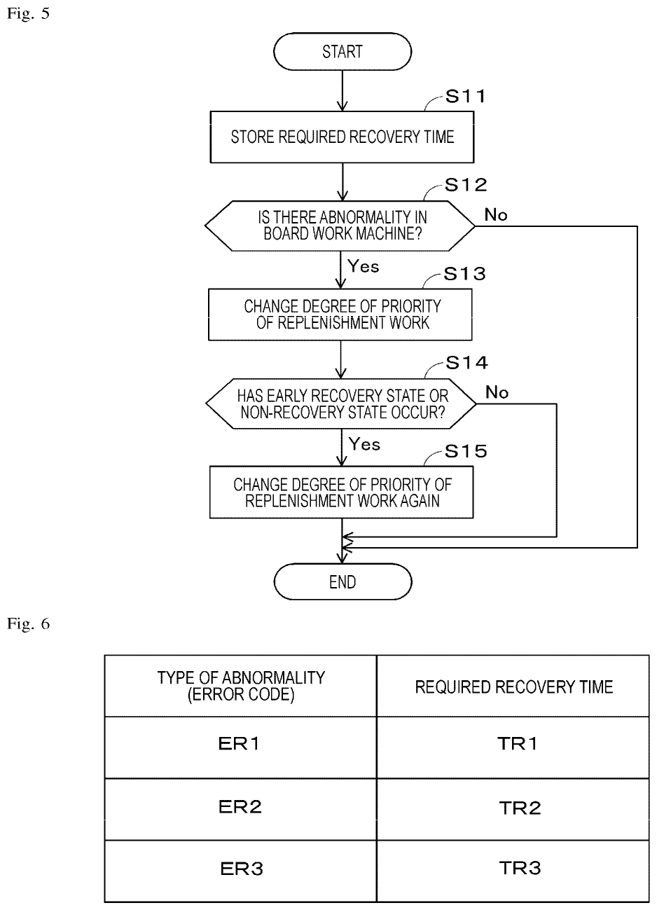

As illustrated in FIG. 4, determination section 81, change section 82, and storage section 83 of the embodiment are provided in management device 70. In addition, article management device 80 executes control according to a flowchart illustrated in FIG. 5. Determination section 81 performs the determination illustrated in step S12. Change section 82 performs the processing and determination shown in steps S13 to S15. Storage section 83 performs the processing illustrated in step S11.

### 1-4-1. Determination Section 81

Determination section 81 determines whether there is an abnormality in multiple board work machines 10 that perform the predetermined board work on board 90 (step S12 shown in FIG. 5). The abnormality of board work machine 10 includes various troubles that may delay the timing of the replenishment work of article 21. For example, the conveyance abnormality of board 90 in board work machine 10 is included in the abnormality of board work machine 10.

In addition, the stack of reel 22a in feeder 23a is included in the abnormality of component mounter 10c which is board work machine 10. The abnormality of a mounting head that collects component 91 and mounts component 91 on board 90 is included in the abnormality of component mounter 10c which is board work machine 10. The failure of a backup battery of the storage device that stores control parameters for a servo motor that drives the mounting head is included in the abnormality of the mounting head.

Determination section 81 can take various forms as long as determination section 81 can determine whether there is an abnormality in multiple board work machines 10. For example, as shown in FIG. 1, each of two production lines 10L includes multiple (six) board work machines 10. Further, two production lines 10L and management device 70 are provided so as to be able to communicate with each other by a wired or wireless communication section. For example, when an abnormality occurs, each of multiple (twelve) board work machines 10 reports the occurrence of the abnormality to management device 70 via the communication section. Similarly, when the abnormality is recovered, each of multiple (twelve) board work machines 10 reports to management device 70 via the communication section that the abnormality is recovered.

The production facility illustrated in FIG. 1 may include a line management device in each of two production lines 10L. The line management device manages board work machine 10 belonging to managed production line 10L. In this case, the line management device of production line 10L to which board work machine 10 in which an abnormality has occurred belongs can also report to management device 70 via the communication section that the abnormality has occurred in board work machine 10. Similarly, the line management device of production line 10L to which board work machine 10 in which an abnormality has occurred belongs can report to management device 70 via the communication section that the abnormality of board work machine 10 has been recovered.

Further, management device 70 can confirm whether there is an abnormality in board work machine 10 for board work machine 10 or the line management device every time a predetermined time elapses. In any of the above cases, management device 70 can recognize whether there is an abnormality in multiple (twelve) board work machines 10. In addition, determination section 81 can recognize whether there is an abnormality in multiple (twelve) board work machines 10.

In addition to the presence or absence of an abnormality in board work machine 10, determination section 81 can acquire various kinds of information relating to the abnormality. For example, determination section 81 can acquire at least one of the identification information for identifying board work machine 10 in which an abnormality has occurred, the type of the abnormality, the portion in which the abnormality has occurred, the severity of the abnormality, the time at which the abnormality has occurred, the time at which the abnormality has been recovered, and the state of board work machine 10 when the abnormality has occurred.

1-4-2. Change section 82 and Storage Section 83

In the present description, at least one of multiple board work machines 10 determined to have no abnormality by determination section 81 is referred to as normal work machine 51. At least one of multiple board work machines 10 determined to have an abnormality by determination section 81 is referred to as abnormal work machine 52. For convenience of description, for example, component mounter 10c which is one of multiple (two) component mounters 10c belonging to one production line 10L among two production lines 10L illustrated in FIG. 1 and is represented by identification number M11 is set as abnormal work machine 52. In addition, component mounter 10c which is another one of multiple (two) component mounters 10c belonging to production line 10L and is represented by identification number M12 is set as normal work machine 51.

Further, component mounter 10c which is one of multiple (two) component mounters 10c belonging to other one production line 10L of two production lines 10L and is represented by identification number M21 is set as normal work machine 51. In addition, component mounter 10c which is another one of multiple (two) component mounters 10c belonging to production line 10L and is represented by identification number M22 is set as normal work machine 51.

Based on the type of abnormality of abnormal work machine 52, change section 82 changes the degree of priority of the replenishment work of replenishing multiple board work machines 10 with articles 21 to be used in multiple board work machines 10 (step S13 shown in FIG. 5). Specifically, when determination section 81 determines that there is an abnormality in at least one of multiple board work machine 10 (Yes in step S12), change section 82 changes the degree of priority of the replenishment work (step S13). When determination section 81 determines that there is no abnormality in at least one of multiple board work machines 10 (No in step S12), the control by article management device 80 is temporarily ended.

As described above, management device 70 instructs storage cabinet 40 to unload article 21 by the component shortage notice. Storage cabinet 40 unloads article 21 (in this case, for example, component container 22 or component supply unit 23) based on the unloading instruction. The time at which article 21 is required in abnormal work machine 52 is later than the expected time calculated by management device 70 before the occurrence of an abnormality. That is, the degree of priority of the replenishment work of replenishing abnormal work machine 52 with article 21 decreases. In this case, the unloading time at which storage cabinet 40 unloads article 21 is later than the expected time calculated by management device 70 before the occurrence of the abnormality.

As described above, the degree of priority of the replenishment work includes the unloading order of articles 21 when storage cabinet 40 storing articles 21 unloads articles 21. In this case, change section 82 can move down the unloading order of articles 21 to be replenished to abnormal work machine 52. That is, change section 82 can delay the unloading time of article 21 to be replenished to abnormal work machine 52 from the expected time calculated before the occurrence of the abnormality.

As described above, management device 70) instructs automated conveyance vehicle 30 to convey article 21 by the component shortage notice. Automated conveyance vehicle 30 conveys article 21 to component mounter 10c based on the conveyance instruction. As in the case of storage cabinet 40, the time at which article 21 is required in abnormal work machine 52 is later than the expected time calculated by management device 70 before the occurrence of the abnormality. That is, the degree of priority of the replenishment work of replenishing abnormal work machine 52 with article 21 decreases. In this case, the conveyance time at which automated conveyance vehicle 30 conveys article 21 to abnormal work machine 52 is later than the expected time calculated by management device 70 before the occurrence of an abnormality.

In this way, the degree of priority of the replenishment work includes the order in which articles 21 are conveyed when automated conveyance vehicle 30 conveying articles 21 conveys articles 21 to multiple board work machines 10. In this case, change section 82 can move down the conveyance order of articles 21 to be replenished to abnormal work machine 52. That is, change section 82 can delay the conveyance time of article 21 to be replenished to abnormal work machine 52 from the expected time calculated before the occurrence of an abnormality. Thus, the degree of priority of the replenishment work includes at least one of the unloading order and the conveyance order of articles 21 described above.

Change section 82 can take various forms as long as change section 82 can change the degree of priority of the replenishment work of article 21 based on the type of abnormality of abnormal work machine 52. For example, change section 82 of the embodiment can change the degree of priority of the replenishment work based on the type of the abnormality of abnormal work machine 52 and the required recovery time which is the required time from the occurrence of an abnormality to the recovery of the abnormality of abnormal work machine 52.

Specifically, storage section 83 stores the required recovery time for each type of abnormality of abnormal work machine 52 in storage device 80m (step S11 shown in FIG. 5). For example, the type of abnormality of board work machine 10 can be represented by an error code or the like. In the example of an abnormality described above, error codes respectively corresponding to the conveyance abnormality of board 90 in board work machine 10 and the abnormality of the stack of reel 22a and the mounting head in feeder 23a are provided.

As shown in FIG. 6, before starting the production of board product 900, storage section 83 stores the required recovery time in storage device 80m for each type of abnormality (error code) of board work machine 10. Storage device 80m may be any known storage device as long as storage device 80m can store the required recovery time. The required recovery time can be acquired in advance by simulation, verification using an actual machine, or the like.

For example, storage device 80m stores error code ER1 indicating a conveyance abnormality of board 90 in board work machine 10 and required recovery time TR1 of the conveyance abnormality in association with each other. In addition, storage device 80m stores error code ER2 indicating the stack of reel 22a in feeder 23a and required recovery time TR2 of the stack in association with each other. Further, storage device 80m stores error code ER3 indicating an abnormality of the mounting head and required recovery time TR3 of the abnormality in association with each other.

It is assumed that articles 21 are unloaded from storage cabinet 40 storing article 21 and replenished to multiple board work machines 10. In this case, change section 82 acquires the required recovery time corresponding to the type of abnormality of abnormal work machine 52 from storage device 80m, and changes the degree of priority of the replenishment work so that storage cabinet 40 unloads article 21 at a time delayed by the required recovery time from the scheduled unloading time of article 21 to be replenished to abnormal work machine 52.

For example, as illustrated in FIG. 7, it is assumed that the degree of priority of the replenishment work is set to be lower in the order of component mounter 10c with identification number M11, component mounter 10c with identification number M21, component mounter 10c with identification number M12, and component mounter 10c with identification number M22 illustrated in FIG. 1 before an abnormality occurs in board work machine 10. For example, management device 70 can set the degree of priority of the replenishment work in ascending order of the grace time until the shortage of the component (ascending order of the time at which article 21 is required) before an abnormality occurs in board work machine 10. In this case, storage cabinet 40 unloads article 21 to be replenished in the order of component mounter 10c with identification number M11, component mounter 10c with identification number M21, component mounter 10c with identification number M12, and component mounter 10c with identification number M22.

The scheduled unloading time of article 21 to be replenished to component mounter 10c with identification number M11 is time T10. The scheduled unloading time of article 21 to be replenished to component mounter 10c with identification number M21 is time T20. The scheduled unloading time of article 21 to be replenished to component mounter 10c with identification number M12 is time T30. The scheduled unloading time of article 21 to be replenished to component mounter 10c with identification number M22 is time T40. In the above example, it is assumed that an abnormality occurs in component mounter 10c with identification number M11 before time T10.

For example, when the type of abnormality of component mounter 10c with identification number M11 which is abnormal work machine 52 is a conveyance abnormality of board 90 in board work machine 10, change section 82 acquires required recovery time TR1 corresponding to error code ER1 from storage device 80m. Then, change section 82 changes the degree of priority of the replenishment work so that storage cabinet 40) unloads article 21 at a time (time T50) delayed by required recovery time TR1 from the scheduled unloading time (time T10) of article 21 to be replenished to component mounter 10c with identification number M11 which is abnormal work machine 52.

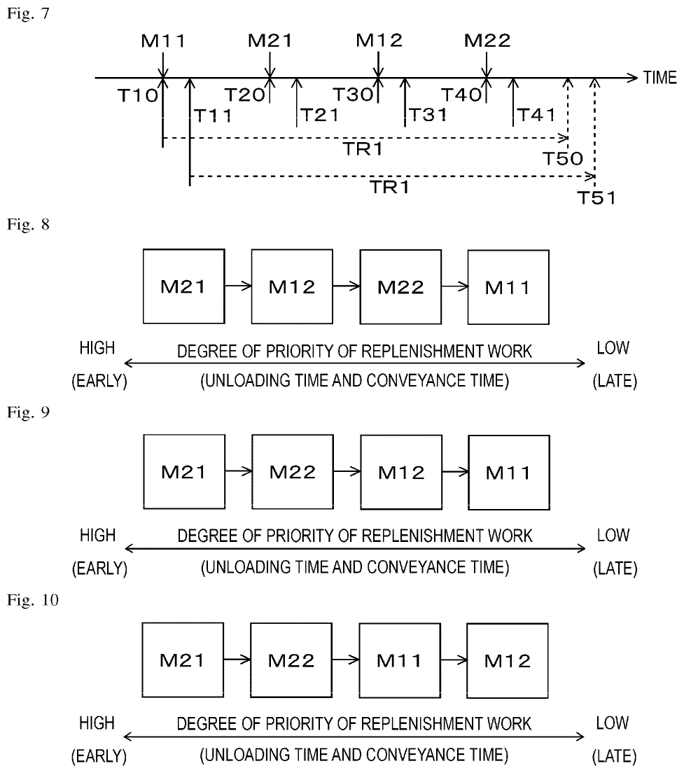

Accordingly, as illustrated in FIG. 8, the degree of priority of the replenishment work is set to be lower in the order of component mounter 10c with identification number M21, component mounter 10c with identification number M12, component mounter 10c with identification number M22, and component mounter 10c with identification number M11. That is, storage cabinet 40 unloads article 21 to be replenished in the order of component mounter 10c with identification number M21, component mounter 10c with identification number M12, component mounter 10c with identification number M22, and component mounter 10c with identification number M11.

It is also assumed that article 21 is replenished to multiple board work machines 10 by automated conveyance vehicle 30 that conveys article 21. In this case, change section 82 acquires the required recovery time corresponding to the type of abnormality of abnormal work machine 52 from storage device 80m, and changes the degree of priority of the replenishment work so that automated conveyance vehicle 30 conveys article 21 at a time delayed by the required recovery time from the scheduled conveyance time of article 21 to be replenished to abnormal work machine 52.

For example, in the example illustrated in FIG. 7, automated conveyance vehicle 30 conveys article 21 to be replenished in the order of component mounter 10c with identification number M11, component mounter 10c with identification number M21, component mounter 10c with identification number M12, and component mounter 10c with identification number M22. In addition, the scheduled conveyance time of article 21 to be replenished to component mounter 10c with identification number M11 is time T11. Time T11 is later than time T10 and earlier than time T20.

The scheduled conveyance time of article 21 to be replenished to component mounter 10c with identification number M21 is time T21. Time T21 is later than time T20 and earlier than time T30. The scheduled conveyance time of article 21 to be replenished to component mounter 10c with identification number M12 is time T31. Time T31 is later than time T30 and earlier than time T40. The scheduled conveyance time of article 21 to be replenished to component mounter 10c with identification number M22 is time T41. Time T41 is later than time T40. In the above example, it is assumed that an abnormality occurs in component mounter 10c with identification number M11 before time T10.

For example, when the type of abnormality of component mounter 10c with identification number M11 which is abnormal work machine 52 is a conveyance abnormality of board 90 in board work machine 10, change section 82 acquires required recovery time TR1 corresponding to error code ER1 from storage device 80m. Then, change section 82 changes the degree of priority of the replenishment work so that automated conveyance vehicle 30 conveys article 21 at a time (time T51) delayed by required recovery time TR1 from the scheduled conveyance time (time T11) of article 21 to be replenished to component mounter 10c with identification number M11 which is abnormal work machine 52.

Accordingly, as illustrated in FIG. 8, the degree of priority of the replenishment work is set to be lower in the order of component mounter 10c with identification number M21, component mounter 10c with identification number M12, component mounter 10c with identification number M22, and component mounter 10c with identification number M11. That is, automated conveyance vehicle 30 conveys article 21 to be replenished in the order of component mounter 10c with identification number M21, component mounter 10c with identification number M12, component mounter 10c with identification number M22, and component mounter 10c with identification number M11.

As shown in FIG. 1, multiple (twelve in the figure) board work machines 10 are provided in multiple (two in the figure) production lines 10L. In the present description, at least one production line 10L of multiple (two) production lines 10L including normal work machine 51 and not including abnormal work machine 52 is referred to as normal line 61. At least one production line 10L of multiple (two) production lines 10L including normal work machine 51 and abnormal work machine 52 is referred to as abnormal line 62.

In normal work machine 51 provided in abnormal line 62, abnormal work machine 52 may become a bottle neck, and the time at which article 21 is required may be delayed compared to normal work machine 51 provided in normal line 61. Change section 82 can lower the degree of priority of the replenishment work in the order of normal work machine 51 provided in normal line 61, normal work machine 51 provided in abnormal line 62, and abnormal work machine 52 provided in abnormal line 62.

For example, in the example illustrated in FIG. 7, it is assumed that an abnormality occurs in component mounter 10c with identification number M11. In this case, component mounter 10c with identification number M21 and component mounter 10c with identification number M22 are normal work machines 51 provided in normal line 61. Component mounter 10c with identification number M12 is normal work machine 51 provided in abnormal line 62. Component mounter 10c with identification number M11 is abnormal work machine 52 provided in abnormal line 62.

Accordingly, as illustrated in FIG. 9, change section 82 can set the degree of priority of the replenishment work to be lower in the order of component mounter 10c with identification number M21, component mounter 10c with identification number M22, component mounter 10c with identification number M12, and component mounter 10c with identification number M11. Accordingly, the replenishment work of article 21 to be replenished to normal work machine 51 provided in normal line 61 is prioritized over the replenishment work of article 21 to be replenished to normal work machine 51 and abnormal work machine 52 provided in abnormal line 62.

In the above case, storage cabinet 40 unloads article 21 to be replenished in the order of component mounter 10c with identification number M21, component mounter 10c with identification number M22, component mounter 10c with identification number M12, and component mounter 10c with identification number M11. In addition, automated conveyance vehicle 30 conveys article 21 to be replenished in order of component mounter 10c with identification number M21, component mounter 10c with identification number M22, component mounter 10c with identification number M12, and component mounter 10c with identification number M11.

When there are multiple abnormal work machines 52, change section 82 can increase the degree of priority of the replenishment work for abnormal work machine 52 whose scheduled recovery time at which abnormal work machine 52 is expected to be recovered is earlier. For example, in the example illustrated in FIG. 7, it is assumed that an abnormality occurs in component mounter 10c with identification number M11 and component mounter 10c with identification number M12. In addition, it is assumed that the scheduled recovery time of component mounter 10c with identification number M1 is earlier than that of component mounter 10c with identification number M12.

In this case, change section 82 can increase the degree of priority of the replenishment work of replenishing component mounter 10c with identification number M11 whose scheduled recovery time is earlier than that of component mounter 10c with identification number M12. For example, change section 82 can set the degree of priority of the replenishment work to be lower in the order of component mounter 10c with identification number M21, component mounter 10c with identification number M22, component mounter 10c with identification number M11, and component mounter 10c with identification number M12.

Further, when there are multiple abnormal work machines 52, change section 82 can increase the degree of priority of the replenishment work for abnormal work machine 52 whose scheduled preparation time at which article 21 is required in abnormal work machine 52 is earlier. For example, in the example illustrated in FIG. 7, it is assumed that an abnormality occurs in component mounter 10c with identification number M11 and component mounter 10c with identification number M12. In addition, it is assumed that the scheduled preparation time of component mounter 10c with identification number M11 is earlier than that of component mounter 10c with identification number M12.

In this case, change section 82 can increase the degree of priority of the replenishment work of replenishing component mounter 10c with identification number M11 whose scheduled preparation time is earlier than that of component mounter 10c with identification number M12. For example, change section 82 can set the degree of priority of the replenishment work to be lower in the order of component mounter 10c with identification number M21, component mounter 10c with identification number M22, component mounter 10c with identification number M11, and component mounter 10c with identification number M12.

When there are multiple abnormal work machines 52, change section 82 can increase the degree of priority of the replenishment work for abnormal work machine 52 provided in abnormal line 62 having a higher operation rate. For example, in the example illustrated in FIG. 7, it is assumed that an abnormality occurs in component mounter 10c with identification number M11 and component mounter 10c with identification number M21. In addition, it is assumed that the operation rate of production line 10L to which component mounter 10c with identification number M11 belongs is higher than that of production line 10L to which component mounter 10c with identification number M21 belongs.

In this case, change section 82 can increase the degree of priority of the replenishment work of replenishing component mounter 10c with identification number M11 belonging to production line 10L having a higher operation rate than production line 10L to which component mounter 10c with identification number M21 belongs. For example, change section 82 can set the degree of priority of the replenishment work to be lower in the order of component mounter 10c with identification number M12. component mounter 10c with identification number M22, component mounter 10c with identification number M11, and component mounter 10c with identification number M21.

In the present description, a state in which abnormal work machine 52 is recovered earlier by a predetermined time or more than a scheduled recovery time at which abnormal work machine 52 is expected to be recovered is referred to as an early recovery state. A state in which abnormal work machine 52 is not recovered even after the predetermined time or more has elapsed from the scheduled recovery time is referred to as a non-recovery state. The predetermined time in the early recovery state or the non-recovery state can be freely set. For example, when the worker recovers the abnormality of abnormal work machine 52, an early recovery state or a non-recovery state may occur.

When an early recovery state or a non-recovery state occurs, change section 82 can change the degree of priority of the replenishment work again (steps S14 and S15 shown in FIG. 5). Specifically, change section 82 determines whether an early recovery state or a non-recovery state has occurred (step S14). As described above, determination section 81 can acquire the time at which an abnormality of board work machine 10) has occurred and the time at which the abnormality has been recovered. Change section 82 can determine whether an early recovery state or a non-recovery state has occurred based on the time at which an abnormality has occurred and the time at which the abnormality has been recovered acquired by determination section 81.

When an early recovery state or a non-recovery state occurs (Yes in step S14), change section 82 changes the degree of priority of the replenishment work again. Specifically, change section 82 recalculates the expected time at which article 21 to be replenished to normal work machine 51, which was abnormal work machine 52, is required, from the time at which abnormal work machine 52 is actually recovered. Change section 82 changes the scheduled unloading time of storage cabinet 40 based on the re-calculated expected time. Further, change section 82 changes the scheduled conveyance time of automated conveyance vehicle 30 based on the re-calculated expected time. Change section 82 changes the degree of priority of the replenishment work of article 21 to be replenished after the time at which abnormal work machine 52 is actually recovered based on the changed scheduled unloading time of storage cabinet 40 and the changed scheduled conveyance time of automated conveyance vehicle 30.

Accordingly, for example, the degree of priority of the replenishment work of article 21 shown in FIG. 9 is changed again, and the unloading time and the conveyance time of article 21 to be replenished to normal work machine 51 which was abnormal work machine 52 are changed. Specifically, as illustrated in FIG. 10, for example, change section 82 can set the degree of priority of the replenishment work to be lower in the order of component mounter 10c with identification number M21, component mounter 10c with identification number M22, component mounter 10c with identification number M11, and component mounter 10c with identification number M12. FIG. 10 illustrates that the early recovery state occurs and the abnormality of component mounter 10c with identification number M11 which was abnormal work machine 52 is recovered earlier than the case illustrated in FIG. 9.

When a non-recovery state occurs, article 21 scheduled to be replenished may be replenished to abnormal work machine 52 in the non-recovery state after article 21 scheduled to be replenished is replenished to another board work machine 10, or article 21 scheduled to be replenished may be replenished after the abnormality of abnormal work machine 52 in the non-recovery state is recovered. When an early recovery state or a non-recovery state does not occur (No in step S14), the control by article management device 80 is temporarily ended.

### 1-4-3. Modification Embodiment

For example, the type of abnormality of board work machine 10 can be classified into a short-term abnormality in which an abnormality is expected to be recovered within a first time after the abnormality occurs in board work machine 10 and a long-term abnormality in which an abnormality is expected to be recovered within a second time longer than the first time after the abnormality occurs in board work machine 10. The first time and the second time can be freely set.

In this case, change section 82 can change the degree of priority of the replenishment work of article 21 based on the type of abnormality (short-term abnormality or long-term abnormality) of abnormal work machine 52. For example, when the type of abnormality of abnormal work machine 52 is the short-term abnormality. change section 82 can change the degree of priority of the replenishment work so that storage cabinet 40 unloads article 21 at a time delayed by the first time from the scheduled unloading time of article 21 to be replenished to abnormal work machine 52. When the abnormality type of abnormal work machine 52 is the long-term abnormality, change section 82 can change the degree of priority of the replenishment work so that storage cabinet 40 unloads article 21 at a time delayed by the second time from the scheduled unloading time of article 21 to be replenished to abnormal work machine 52.

Similarly, when the type of abnormality of abnormal work machine 52 is the short-term abnormality, change section 82 can change the degree of priority of the replenishment work so that automated conveyance vehicle 30 conveys article 21 at a time delayed by the first time from the scheduled conveyance time of article 21 to be replenished to abnormal work machine 52. When the abnormality type of abnormal work machine 52 is the long-term abnormality, change section 82 can change the degree of priority of the replenishment work such that automated conveyance vehicle 30 conveys article 21 at a time delayed by the second time from the scheduled conveyance time of article 21 to be replenished to abnormal work machine 52. The abnormality of abnormal work machine 52 may be classified into three or more types such as a short-term abnormality, a medium-term abnormality, and a long-term abnormality.

In any of the forms described above, change section 82 can also change the degree of priority of the replenishment work by using the degree of priority of the replenishment work specified by a user of board work machine 10. Further, in any of the forms described above, change section 82 can appropriately change the degree of priority of the replenishment work based on the actual unloading state and the actual conveyance state of article 21. For example, it is assumed that automated conveyance vehicle 30 conveys article 21 to board work machine 10. When automated conveyance vehicle 30 is about to reach board work machine 10, it may be more efficient to cause automated conveyance vehicle 30 to convey article 21 to board work machine 10 than to cause automated conveyance vehicle 30 to stop conveying article 21. Change section 82 can cause automated conveyance vehicle 30 to return article 21 to storage cabinet 40, and can also cause automated conveyance vehicle 30 to convey article 21 to another board work machine 10 to which article 21 of the same type as article 21 is scheduled to be conveyed.

Further, in the embodiment, article management device 80 is applied to the replenishment work of article 21 by a component shortage notice. However, article management device 80 can be applied to the replenishment work of various articles 21. For example, article management device 80 can also be applied to the replenishment work of article 21 due to the occurrence of shortage of article 21 such as component shortage. Article management device 80 can also be applied to the replenishment work of article 21 by the setup change.

Further, in the embodiment, at least one of multiple board work machines 10 includes component mounter 10c that mounts component 91 on board 90. Further, article 21 is component container 22 that accommodates component 91 mounted on board 90 or component supply unit 23 that supplies component 91 accommodated in component container 22 to the collection position. Component container 22 includes reel 22a. Component container 22 includes component tray 22b. Further, component supply unit 23 includes feeder 23a. Component supply unit 23 includes tray pallet 23b. Article management device 80 can also be applied to board work machine 10 other than component mounter 10c, and can also be applied to article 21 other than component container 22 and component supply unit 23.

### 2. Article Management Method

The above description of article management device 80 can be similarly applied to an article management method. Specifically, the article management method includes a determination step and a change step. The control performed by determination section 81 corresponds to the determination step. The change step corresponds to the control performed by change section 82. The article management method may include a storage step. The control performed by storage section 83 corresponds to a storage step.

### 3. Example of Effects of Embodiment

Article management device 80 includes determination section 81 and change section 82. Accordingly, article management device 80 can change the degree of priority of the replenishment work of article 21 based on the type of abnormality of abnormal work machine 52 in which an abnormality has occurred. The above description of article management device 80 can be similarly applied to an article management method.

### REFERENCE SIGNS LIST

10: board work machine, 10L: production line, 10c: component mounter, 21: article, 22: component container, 23: component supply unit, 30: automated conveyance vehicle, 40: storage cabinet, 51: normal work machine, 52: abnormal work machine, 61: normal line, 62: abnormal line, 80: article management device, 81: determination section, 82: change section, 83: storage section, 80m: storage device, 90: board, 91: component

1. An article management device comprising:
a determination section configured to determine whether there is an abnormality in multiple board work machines configured to perform a predetermined board work on a board; and
a change section configured to change a degree of priority of a replenishment work of replenishing the multiple board work machines with articles used in the multiple board work machines based on a type of abnormality in an abnormal work machine that is at least one of the multiple board work machines determined to have an abnormality by the determination section.

2. The article management device according to claim 1, wherein the degree of priority of the replenishment work includes an unloading order of the articles when a storage cabinet configured to store the articles unloads the articles.

3. The article management device according to claim 1, wherein the degree of priority of the replenishment work includes a conveyance order of the articles when an automated conveyance vehicle configured to convey the articles conveys the articles to the multiple board work machines.

4. The article management device according to any claim 1, wherein the change section changes the degree of priority of the replenishment work based on the type of abnormality of the abnormal work machine and a required recovery time that is a required time from occurrence of the abnormality in the abnormal work machine to recovery of the abnormality.

5. The article management device according to claim 4, further comprising:
a storage section configured to store the required recovery time for each type of abnormality of the abnormal work machine in a storage device, wherein
the articles are unloaded from a storage cabinet configured to store the articles and replenished to the multiple board work machines, and
the change section acquires the required recovery time corresponding to the type of abnormality of the abnormal work machine from the storage device to change the degree of priority of the replenishment work so that the storage cabinet unloads the article at a time delayed by the required recovery time from a scheduled unloading time of the article to be replenished to the abnormal work machine.

6. The article management device according to claim 4, further comprising:
a storage section configured to store the required recovery time for each type of abnormality of the abnormal work machine in a storage device, wherein
the articles are replenished to the multiple board work machines by an automated conveyance vehicle configured to convey the articles, and
the change section acquires the required recovery time corresponding to the type of abnormality of the abnormal work machine from the storage device to change the degree of priority of the replenishment work so that the automated conveyance vehicle conveys the article at a time delayed by the required recovery time from a scheduled conveyance time of the article to be replenished to the abnormal work machine.

7. The article management device according to claim 1, wherein
the multiple board work machines are provided in multiple production lines, and
the change section lowers the degree of priority of the replenishment work in order of a normal work machine provided in a normal line that is at least one of the multiple production lines and includes at least one normal work machine among the multiple board work machines which is determined to have no abnormality by the determination section and does not include the abnormal work machine, the normal work machine provided in an abnormal line that is at least another one of the multiple production lines and includes the normal work machine and the abnormal work machine, and the abnormal work machine provided in the abnormal line.

8. The article management device according to claim 7, wherein when there are the multiple abnormal work machines, the change section increases the degree of priority of the replenishment work for the abnormal work machine of which a scheduled recovery time at which the abnormal work machine is expected to be recovered is earlier.

9. The article management device according to claim 7, wherein when there are the multiple abnormal work machines, the change section increases the degree of priority of the replenishment work for the abnormal work machine of which a scheduled preparation time at which the article is required in the abnormal work machine is earlier.

10. The article management device according to claim 7, wherein when there are the multiple abnormal work machines, the change section increases the degree of priority of the replenishment work for the abnormal work machine provided in the abnormal line having a higher operation rate.

11. The article management device according to claim 1, wherein the change section changes the degree of priority of the replenishment work again when an early recovery state in which the abnormal work machine is recovered earlier by a predetermined time or more than a scheduled recovery time at which the abnormal work machine is expected to be recovered, or a non-recovery state in which the abnormal work machine is not recovered even after the predetermined time or more has elapsed from the scheduled recovery time occurs.

12. The article management device according to claim 1, wherein
at least one of the multiple board work machines includes a component mounter configured to mount a component on the board, and
the article is a component container configured to accommodate the component to be mounted on the board or a component supply unit configured to supply the component accommodated in the component container to a collection position.

13. An article management method comprising:
a determination step of determining whether there is an abnormality in multiple board work machines configured to perform a predetermined board work on a board; and
a change step of changing a degree of priority of a replenishment work of replenishing the multiple board work machines with articles used in the multiple board work machines based on a type of abnormality in an abnormal work machine that is at least one of the multiple board work machines determined to have an abnormality by the determination step.
